(19) United States
(12) Patent Application Publication
(10) Pub. No.: US 2015/0063010 A1
(43) Pub. Date: Mar. 5, 2015

(54) NEGATIVE BIAS THERMAL INSTABILITY STRESS TESTING FOR STATIC RANDOM ACCESS MEMORY (SRAM)

(71) Applicant: Synopsys, Inc., Mountain View, CA (US)

(72) Inventors: Jamil KAWA, Campbell, CA (US); Tzong-Kwang Henry YEH, Los Gatos, CA (US); Shih-Yao Christine SUN, San Jose, CA (US); Raymond Tak-Hoi LEUNG, Palo Alto, CA (US)

(21) Appl. No.: 14/461,338

(22) Filed: Aug. 15, 2014

Related U.S. Application Data
(60) Provisional application No. 61/870,772, filed on Aug. 27, 2013.

(51) Int. Cl. G11C 29/04; G11C 11/419

(52) U.S. Cl. CPC G11C 29/04; G11C 11/419
USPC 365/154

(57) ABSTRACT

In one embodiment, one portion of an SRAM array is stressed by first writing a “1” in every bit of the array, followed by an evaluation of the relevant parameters of the array using a ring oscillator driven by a mirrored bit-line current, the ring oscillator not in line of the bit-line of the SRAM. The other portion of the array is then stressed after writing a “0” in every bit of the array. The evaluation procedure is then repeated.

### RELATED APPLICATIONS

The present application claims priority to U.S. Provisional Patent No. 61/870,772, filed on Aug. 27, 2014, and incorporates that application by reference in its entirety.

### FIELD

The present invention relates generally to Negative Bias Thermal Instability (NBTI) evaluation of CMOS transistors in SRAM arrays and circuits.

### BACKGROUND

CMOS semiconductor transistors, both P-type and N-type are identified with two associated parameters, namely their threshold voltage—the voltage needed between the gate of a transistor and its source to turn it on—and their saturation current as a reflection of their drive strength. These two transistor parameters, the threshold voltage and the saturation current, are reflected in the speed of circuits in which such transistors are used as basic components.

CMOS transistors, P-type and N-type undergo a change—degradation—in their threshold voltage and saturation current over time. This degradation in the threshold voltage and saturation current of a transistor takes the form of an increase in the magnitude of the threshold voltage and a decrease in the magnitude of the saturation current.

One phenomenon is elevated electric fields between the gate of the transistor and its drain, known as hot carrier injection (HCl) resulting in a permanent shift in threshold voltage. Another phenomenon is “biased thermal instability” (BTI) that causes partially recoverable degradation in the threshold voltage of the transistor. BTI is highly dependent on temperature, total switching time, and the switching behavior of the transistor also known as the switching duty cycle. The BTI induced change in the threshold voltage and saturation current of P-transistors is referred to as “negative bias thermal instability” (NBTI).

The NBTI phenomenon is a partially reversible process. When the applied source-to-gate bias is removed, the transistor is capable of recovering part of the change in threshold voltage and in saturation current brought about by the applied bias. The amount of recovery is heavily dependent on the duration of the absence of any source-to-gate bias.

Modeling NBTI is important for accurate circuit simulation. Because of the partial recovery aspect of NBTI, accurate modeling is heavily dependent on minimizing the amount of time between the application of the source-to-gate bias and the measurement of the magnitude of change in the threshold voltage and saturation current.

SRAM arrays consist of bit-cells. In SRAM cells the relative strength of P-type transistors to N-type transistors dominated by these two parameters, and this relationship also determines the ease of reading a cell, writing to a cell, it's speed, and critical cell parameters such as static noise margin (SNM). Therefore, these two parameters can be considered to characterize the SRAM array.

The degradation of the P-type transistor and N-type transistor over time is not symmetrical. It can be significantly skewed resulting in an alteration of an SRAM cell critical parameters especially readability and SNM. There are several physics based phenomena that cause such degradation. Therefore, accurate characterization of the degradation parameters of the SRAM cell is very useful for circuit design.

FIG. 1 illustrates a standard NBTI test setup for evaluating the NTBI effects in a transistor representing the current state of the art. A bench tester 10 applies an external voltage bias of zero volts to the gate of the transistor P10 and measures the current flowing through the transistor. Then the P-transistor P10 is stressed by applying a stress voltage Vg at the gate of the transistor P10 and applying a voltage Vdd, equal to the source voltage of P10, at the drain of the transistor P10 to keep the potential between the source and the drain of P10 at zero during the stress phase of the test as shown in waveform 20. After the stress period is complete, the tester 10 releases the applied voltages to the gate and drain of transistor P10 and re-applies a bias of zero volts to the gate of the transistor P10. The tester then measures the new value of the current flowing through the transistor. There is usually a delay between the stress phase and the measurement phase determined by the tester limitations and specifications. During this delay, the transistor partially recovers from the NBTI effects. Thus the measured NBTI effect is lower than the actual NBTI effect.

The transistors of bit-cells with identical layout exhibit a distribution of threshold voltage and saturation current characteristic of the transistor manufacturing technology. This translates to a corresponding distribution of cell read current.

Transistors of an SRAM array undergo NBTI aging. However, currently the NBTI aging of SRAM arrays and of the corresponding distribution of post NBTI stress cell readability and read current are not evaluated.

### BRIEF DESCRIPTION OF THE FIGURES

The present invention is illustrated by way of example, and not by way of limitation, in the figures of the accompanying drawings. The novel features believed characteristic of the invention are set forth in the appended claims. The invention itself, however, as well as a preferred mode of use, further objectives, and advantages thereof, will best be understood by reference to the following detailed description of an illustrative embodiment when read in conjunction with the accompanying drawings, wherein like reference numerals indicate like components, and:

FIG. 1 is a diagram of a classical setup (prior art) for measuring NBTI of a transistor using a tester/bench set-up.

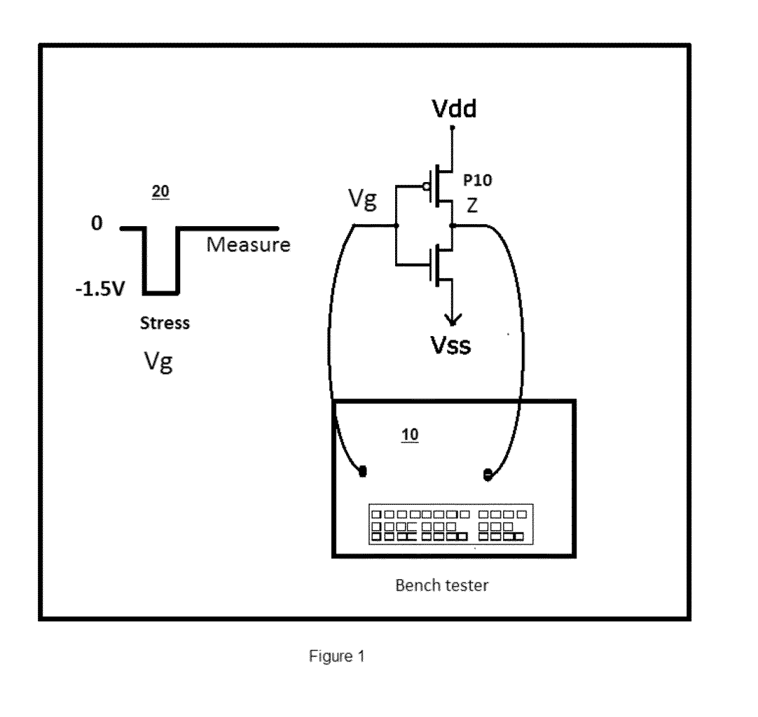

FIG. 2 is a circuit block diagram of one embodiment of an SRAM array and the control circuitry of the present invention.

FIG. 3 is a circuit diagram of one embodiment of the bit-cell read current test circuit.

FIG. 4 is a block diagram of one embodiment of an SRAM array slice showing the content and connectivity of a memory cell.

FIG. 5 is a flowchart of one embodiment of the invention.

FIG. 6 is a timing diagram for the process shown in the flowchart of FIG. 5.

FIG. 7 is a flowchart of another embodiment of the invention.

FIG. 8 is a diagram showing an exemplary ring oscillator output before and after NBTI stress.

FIG. 9 is a flowchart of one embodiment of the bit-cell read dynamic testing cycle.

FIG. 10 is an exemplary simulation of the I-read and oscillator output distribution of an SRAM array.

### DETAILED DESCRIPTION

The objective of this invention is to accurately determine the change in a CMOS P-type transistor threshold voltage and saturation current of the bit-cells of an SRAM array, and the corresponding shift in readability and read current, read current distribution, SNM, and writability of the SRAM array resulting from NBTI. This invention describes a method of dynamic NBTI stress of SRAM arrays and in one embodiment utilizes patent application Ser. No. 14/461,319 (Attorney Reference No. 2986P2288US02) and patent application Ser. No. 14/461,327 (Attorney Reference No. 2986P2347US02), filed concurrently herewith to evaluate the pre-NBTI stress and post-NBTI stress shift in an SRAM array bit-cells transistor behavior and in the pre-NBTI and post-NBTI distribution of bit-cell read current.

In one embodiment, one half of an SRAM array is stressed at a time by first writing a “1” in every bit of the array using a standard write operation, followed by an evaluation of the relevant parameters of the array. The other half of the array is then stressed after writing a “0” in every bit of the array, again using a standard write operation. The evaluation procedure is then repeated. Of course, set-ups testing the SRAM array in smaller groups, rather than half of the array at once, may be used. One of ordinary skill in the art would understand that the SRAM array testing may be done on any sub-portion of the SRAM.

In another embodiment, one half of the array is stressed at time using an alternate methodology that does the writing of the “1” in one step, followed by the evaluation procedure, followed by writing the “0” all in one step and then following that with the evaluation procedure.

The evaluation procedure characterizes the SRAM, and provides data about array static-noise margin (SNM), readability, writability, and read current distribution of an SRAM after extended use. This information is used in EDA, design, and verification processes to ensure that the device will function properly after the SRAM has been stressed by real use.

The foregoing and other objectives, features, and advantages of the invention will be apparent from the following, more particular description of the preferred embodiment of the invention, as illustrated in the accompanying drawings.

The process concerns circuits and methodologies for stressing and then evaluating the Negative Bias Thermal Instability (NBTI) of the CMOS P-type transistors of the bit-cells of an SRAM array. The circuits and methods described provide flexible and accurate measurement of threshold voltage and of saturation current degradation caused by NBTI. This is referred to in the application as characterizing the SRAM. The process also allows for accurate evaluation of an SRAM array static-noise margin (SNM), readability, writability, and read current distribution post NBTI stress. The NBTI stress testing provides useful data for the behavior of an SRAM after extended use, and is used to ensure that the SRAM will continue to function properly over time. It also provides data for determining the needed level of read assist for proper functioning of the array over time.

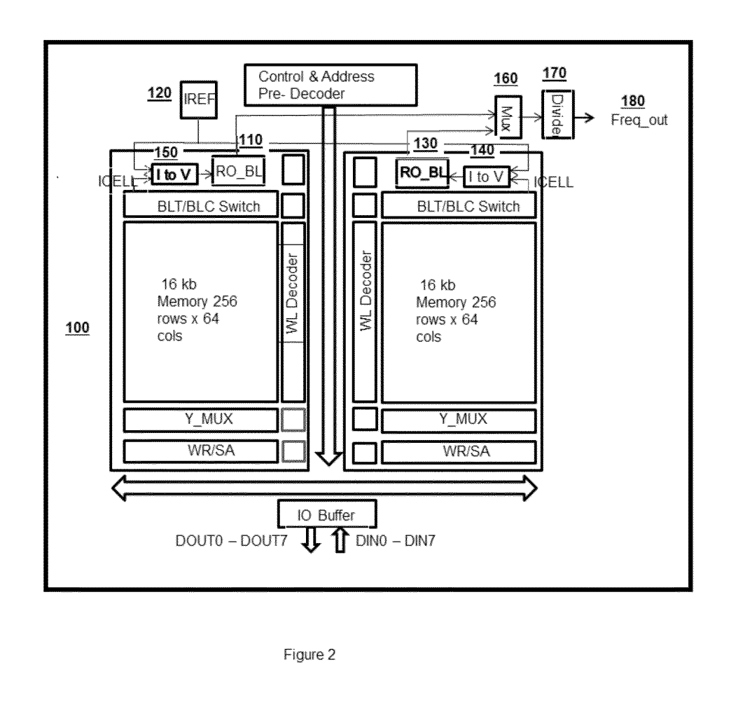

FIG. 2 is a block-level architectural diagram of a representative 32K bit SRAM array and control circuitry implementing the present invention. A typical SRAM memory architecture 100 with multiple banks (here it is two of 16 kb each organized as 256 words by 64 columns), word-line decoders, bit-line switches, and 10 buffers is shown. Elements 110, through 180 are representative blocks of one embodiment of the invention. Ring oscillators 110 and 130 are ring oscillator blocks supporting the two banks of the SRAM array.

In one embodiment, current mirror and current to voltage converter 140, 150 are coupled to the SRAM 100. The current mirror senses and mirrors the current of a bit-line. The bit-line current is converted to a voltage by a current to voltage converter 150, 140 that powers a ring oscillators 110 and 130, respectively. In one embodiment, a current mirror and current to voltage converter is associated with each ring oscillator. In this example, two current mirrors are illustrated 110 and 130. However, one of skill in the art would understand that there may be more or fewer ring oscillators used.

A reference bit-cell current 120 is also mirrored and converted to a voltage, by current mirror and current to voltage converter, to drive the same ring oscillator 110, 130 to establish a reference frequency. The reference frequency is used for providing a baseline, comparing the frequency of the ring oscillator 110, 130 driven by bit-line mirrored current to that of the same ring oscillator 110, 130 driven by the reference current.

In one embodiment, the reference current value is established by a reference circuit based on the simulation of the nominal bit-line parasitics and nominal bit-cell drive current.

The current to voltage converter 150 is used in one embodiment. In another more basic embodiment, the mirrored-current circuit as well as the reference current IREF 120 drive the ring oscillators 110 and 130 directly. In one embodiment, the circuit may include multiplexer 160. Multiplexer 160 multiplexes the outputs of the ring oscillators 110 and 130 supporting the main two banks of the SRAM array.

In one embodiment, the circuit may include divider 170. Divider 170 is a divide by “n” circuit for the output of the ring oscillator to make the sensed frequency 180 easier to measure by a generic tester. The number “n” is arbitrary. A typical number for n is “8”. Direct sensing of frequency 180 is one embodiment of the implementation. Using frequency 180 as an input to a counter is another embodiment. Other methods of evaluating the frequency may be utilized.

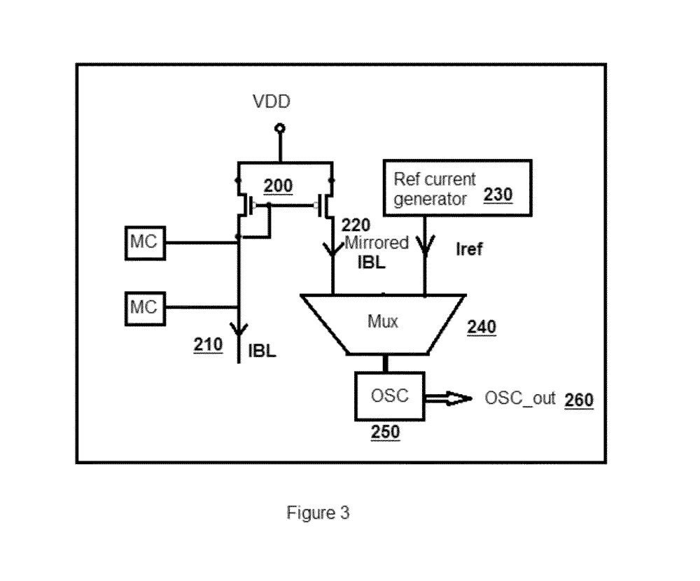

Referring now to FIG. 3, details of the basic embodiment of the circuit are shown. A classical current-mirror circuit 200 generates mirrored isolated bit-line current (IBL) 220. Mirrored IBL 220 is the same as the IBL current 210. A reference current generator 230 generates Iref, reflecting the simulated Iread of a typical SRAM bit-cell under nominal conditions. The Iref is used to establish a reference oscillator frequency to current level conversion. In one embodiment, multiplexer 240 is used to multiplex IBL 210 with mirrored IBL 220 to enable the use of the same ring oscillator 250 for establishing the reference frequency as well as the measured frequencies of the mirrored IBL. The output 260 of the ring oscillator 250 is sensed. In one embodiment, the output 260 is sensed directly. In one embodiment, the output 260 is sensed after a divide-by circuit, or through a counter. All such sensing techniques are well established in the art and are not relevant to the invention.

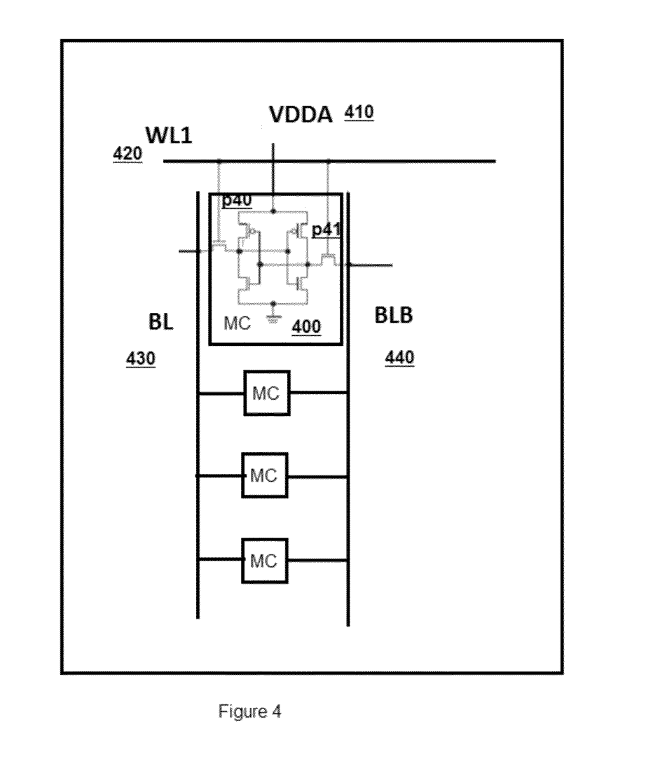

In FIG. 4 an exemplary cross section of a typical SRAM array including the word-line 420, the bit-line (BL) 430, and the bit-line complement 440 (BLB). VDDA 410 is the power supply for the core modules. FIG. 4 also shows a lower level illustration of a single typical memory cell (MC) 400 showing the pull-up devices p40 and p41 as well as the pass devices and pull-down devices. The system described tests the degradation of the pull-up devices p40 and p41, and its impact on SRAM parameters. Historically, SRAM wasn't tested for device degradation because of the density and complexity of the memory cells.

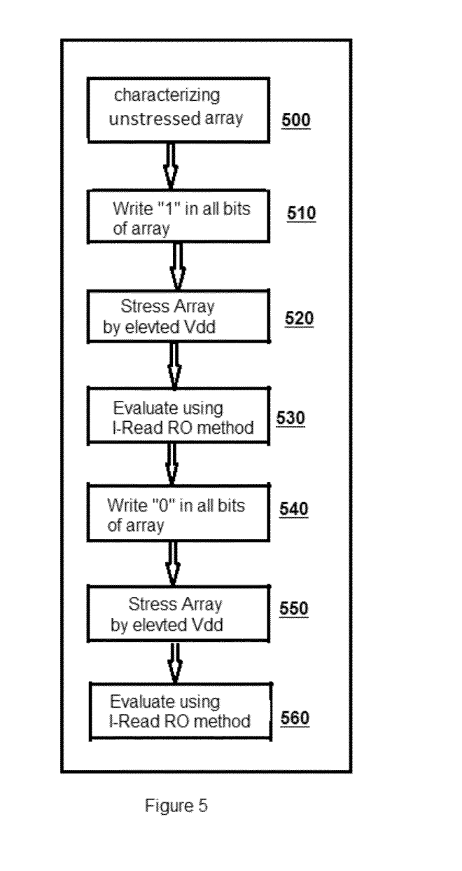

FIG. 5 is a flowchart of one of the embodiment of the invention. The starting point is a fresh unstressed SRAM. In one embodiment, a pre-stress characterization is performed on the unstressed SRAM (block 500). The pre-stress characterization uses the ring oscillator as a proxy to measure the SRAMs threshold voltage and saturation current. The output of the ring oscillator is indicative of the threshold voltage and saturation current of the unstressed SRAM. As noted above, these factors impact the SRAM cell critical parameters especially readability and SNM.

The next step is to write all “1s” to all the bit-cells of the array (block 510). This is done to ensure that all the left-half internal P-devices of all bit-cells—p40 of FIG. 4 is a representative device—are in the “on” state with their gates at VSS level (zero) and all the P-devices of the right-half of the bit-cells of the array—p41 of FIG. 4 is a representative device—are in the “off” state with their gates sitting at VDDA.

Then the array is stressed by de-asserting all word lines (set to “low”) and elevating VDDA to a pre-determined stress level for the desired stress duration (block 520). Note that by de-asserting all word lines, the value of BL 430, and BLB 440 (shown in FIG. 4) become irrelevant. This type of stressing of P-type devices is known in the art. During the stressing, the ring oscillator is disconnected from the system, so that the circuit elements of the ring oscillator itself are not impacted by the stress phase of the stress test.

The stress is then removed and the array is immediately characterized post-stress (block 530). In one embodiment, the post-stress characterization utilizes the same procedure and circuit elements as used in the pre-stress characterization. That is, the ring oscillator is coupled to the mirrored bit-line current, and the output of the ring oscillator is used to evaluate the threshold voltage and saturation current of the SRAM.

Then, to test the other half of the SRAM, a write of all “0s” is performed to render all the un-stressed right-half P-devices of the array—p41 of FIG. 4 is a representative device—in the “on” state and ready to be stressed (block 540).

The stress procedure described above is repeated, by de-asserting all word-lines and elevating VDDA to the desired stress levels (block 550). The SRAM array is re-characterized, using the ring oscillator, after all its P-devices have undergone the desired stress (block 560).

One of ordinary skill in the art will recognize that the process of FIG. 5 is a conceptual representation of the operations used to stress test an SRAM array. For example, a smaller portion of the SRAM may be tested at a time, the order of stressing could be reversed, or other alterations could be made. The specific operations of the process may not be performed in the exact order shown and described. The specific operations may not be performed in one continuous series of operations, and different specific operations may be performed in different embodiments. Furthermore, the process could be implemented using several sub-processes, or as part of a larger macro process.

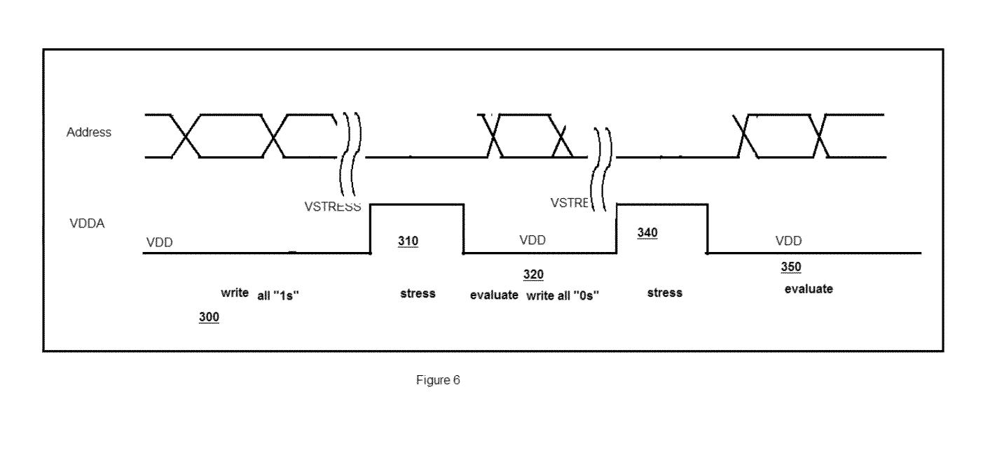

FIG. 6 is a representative timing diagram of process described in FIG. 5. The standard control signals such as write-enable and data-in are not shown as their relationship to address and other signals is well understood and is not part of the scope of the invention. FIG. 6 shows the write all “1s” phase 300 with VDDA at normal nominal VDD value, followed by the stress phase 310 where the address lines are low before VDDA is elevated to VDDSTRESS. This is followed by an evaluate phase 320, where addresses are normally selecting the bits to be characterized. The second stress test, phase 340 occurs after the 0s are written, followed by a second evaluate phase 350. The output of the ring oscillator after the stress tests is used to characterize the SRAM. It must be made clear that the order of writing the “1s” and “0s” is arbitrary and has no significance.

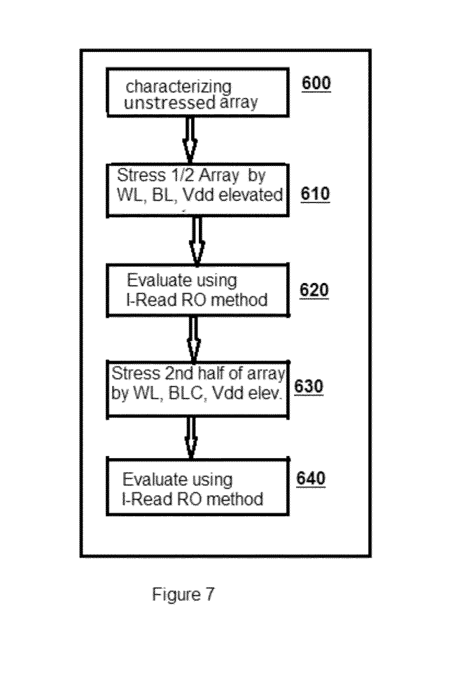

FIG. 7 is a flowchart of another embodiment of the invention where one half the array is stressed in a single operation. It achieves the same objective of writing all “1s,” applying stress, and evaluating the results of the stress in a single phase.

The starting point is the characterization of the unstressed SRAM array (block 600). As described above, this is done using the ring oscillator, in one embodiment.

The process then writes all “1s” to the memory cells, and performs the stress test in a single procedure (block 610). This is done by having the word-line WL, bit-line BL, and core power supply VDDA all elevated to VSTRESS, while bit-line compliment BLB is held low at the “0 level.” Then the stress phase is lifted and a the results of the stress phase are evaluating in the evaluate phase (block 620).

The second half of the array is stressed by keeping BL at “0” and elevating BLB, VDDA, and WL to VSTRESS (block 630). This writes all 0s, and performs the stress test simultaneously. Then an evaluate phase commences (block 640). This enables a fast characterization of the SRAM and the effects of stress on the SRAM, to evaluate the SRAM's likely degradation due to NTBI.

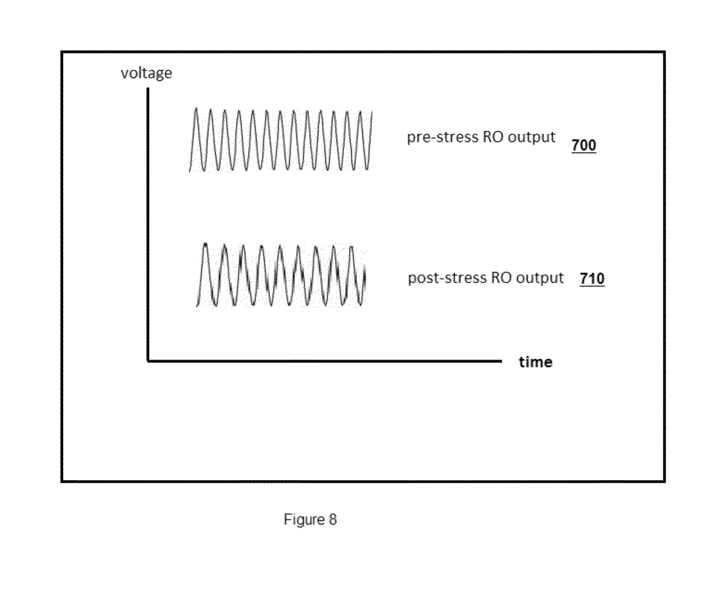

FIG. 8 is a representative expected change in oscillation frequency between an unstressed array 700 and a stressed array 710. The change in output frequency, OSC_OUT, reflects the degradation of the SRAM that can be expected due to NTBI. As noted above, a circuit partial recovery from NTBI occurs relatively quickly, but these effects must be accounted for when designing the circuit, to ensure that the circuit will function well over time.

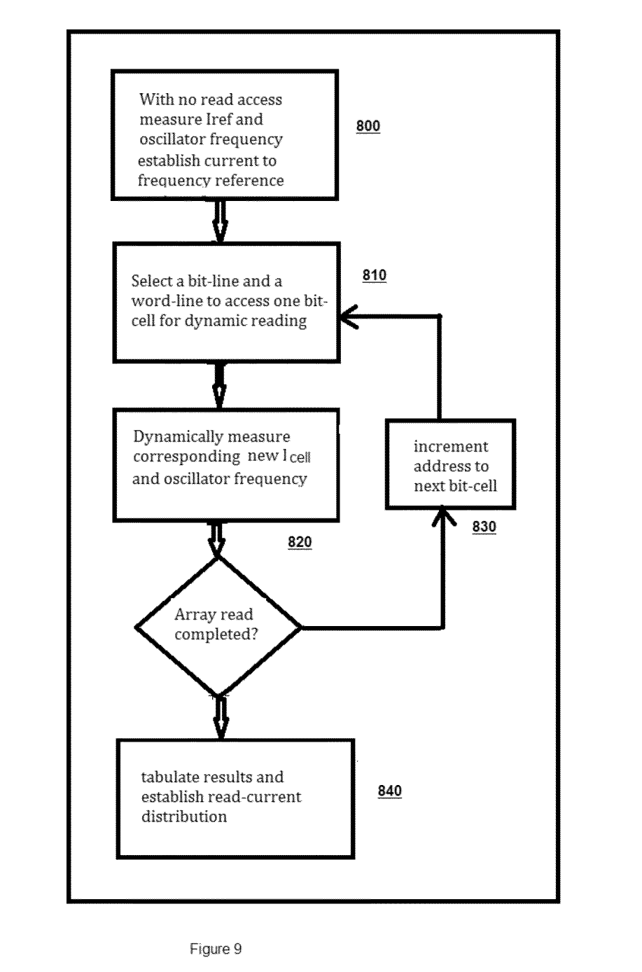

FIG. 9 is a flowchart of one embodiment of a typical Iread test sequence for evaluating the array pre and post stress. At block 800 the process establishes the reference Iread and reference frequency as a basis for measurement and comparison. This is equivalent to characterization of the unstressed SRAM array.

At block 810, an address is asserted, resulting in a selected bit-line and a selected word-line translating to a bit-line discharging through a bit-cell. At block 820, a mirrored IBL is generated and used to drive a ring oscillator whose oscillation frequency is measured. The procedure is repeated for the next bit-cell through incrementing the address, at block 830, until the selected bits and bit-line/bit Iread instances are characterized. In one embodiment, the results are tabulated 840 and Iread distribution is established.

This tabulated result is then used to characterize the SRAM array. This characterization an then be used as part of a model of the SRAM array, which provides the timing, power requirements, and characteristics of the SRAM array. The collection of such models may be referred to as a library. The model from the library can be used in circuit design, to ensure that the timing and power requirements of the SRAM are met in the design. The characterization can also be used in SRAM design, to ensure reasonable yield of electronic components that meet all the system speed requirements expected of an SRAM. The characterization can also be used when setting tolerances for an SRAM, to ensure that the static noise margin of the SRAM remains in the acceptable range in use.

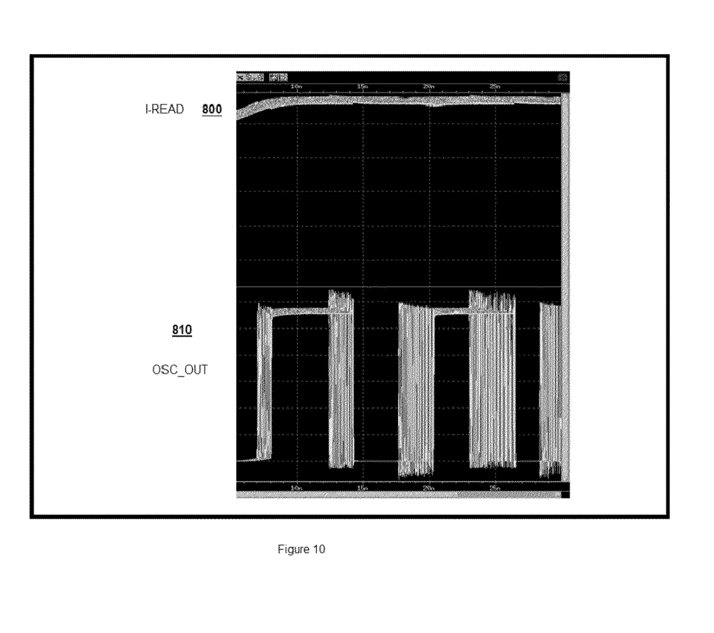

FIG. 10 is a simulation representation of an exemplary Iread distribution 800 and the corresponding oscillator output, OSC_OUT, frequency distribution 810.

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

We claim:

1. A method of evaluating negative bias thermal instability stress test effects on a static random-access memory (SRAM) comprising:
characterizing an unstressed SRAM array;
stressing the SRAM array by elevating a source-gate voltage for a subset of P-devices in the SRAM array whose gates are at zero to a stress level;
releasing the stressing; and
characterizing the SRAM array using a ring oscillator coupled to a mirrored bit-line current, the output of the ring oscillator representing a threshold voltage and saturation current of the SRAM array after stressing.

2. The method of claim 1, wherein the stressing further comprises:
writing into the SRAM array, and disabling word lines during the stressing, while raising a core power supply (VDDA) to the stress level.

3. The method of claim 1, wherein the stressing comprises:
stressing a first portion of the SRAM array through writing all “1s” and elevating a core power supply (VDDA) to the stress level, while disabling word-lines; and
stressing a second portion of the SRAM array by writing all “0s” and elevating the VDDA to the stress level while disabling word-lines.

4. The method of claim 3, wherein a first characterizing occurs after stressing the first portion of the SRAM array and a second characterizing occurs after stressing the second portion of the SRAM array.

5. The method of claim 1, further comprising:
characterising the unstressed SRAM array using a reference frequency, the ring oscillator driven by the mirrored bit-line current to the frequency of the ring oscillator driven by the reference current.

6. The method of claim 5, wherein the reference current value is established by a reference circuit based on the simulation of the nominal bit-line parasitics and nominal bit-cell drive current.

7. The method of claim 1, wherein data from the characterizing of the SRAM is used to set read current and read timing for SRAMs.

8. The method of claim 1, further comprising:
adding the characterization information of the SRAM array to a library, the library used in circuit design.

9. A method of stressing an SRAM array for negative bias thermal instability (NBTI) evaluation comprising: raising a bit-line, a word line, and a core power supply (VDDA) to high, while maintaining bit-line bar at zero, thereby stressing half of P-devices in the SRAM array;
releasing the stressing; and
characterizing the SRAM array using a ring oscillator coupled to a mirrored bit-line current, the output of the ring oscillator representing a threshold voltage and saturation current of the SRAM array.

10. The method of claim 9, wherein the stressing further comprises:
raising the bit-line bar, the word line, and VDDA to high, while maintaining bit-line at zero, thereby stressing another half of P-devices in the SRAM array.

11. The method of claim 10, wherein the characterizing occurs after stressing the first half of the P-devices, and after stressing the second half of the P-devices.

12. The method of claim 10, further comprising:
characterising an unstressed SRAM array using a reference frequency, the frequency of the ring oscillator driven by the mirrored bit-line current to the frequency of the ring oscillator driven by the reference current.

13. The method of claim 12, wherein the reference current value is established by a reference circuit based on the simulation of the nominal bit-line parasitics and nominal bit-cell drive current.

14. A circuit for stressing an SRAM array comprising:
an SRAM array;
a current mirror coupled to a bit-line of the SRAM array, the current mirror to mirror a bit-line current;
a ring oscillator driven by the mirrored bit-line current;
wherein the SRAM array is stressed by writing into the SRAM array, and the ring oscillator is used to characterize changes to the SRAM as a result of the stressing.

15. The circuit of claim 14, wherein the stressing comprises:
writing a 1 into the SRAM array, to stress half of the SRAM array, and writing a 0 into the SRAM array to stress the other half of the SRAM array.

16. The circuit of claim 14, wherein the stressing the SRAM array is done by raising VDDA to a stress level, while maintaining word lines at zero, thereby elevating a source-gate voltage for a subset of p-devices in the SRAM array whose gates are at zero.

17. The circuit of claim 14, wherein the stressing the SRAM array is done by raising a word line, and VDDA to high, and raising one of a bit-line or bit-line bar to high, while maintaining the other of the bit-line or bit-line bar at zero, thereby stressing half of P-devices in the SRAM array.

18. The circuit of claim 14, further comprising:
a reference current generator, the frequency of the ring oscillator driven by the mirrored bit-line current compared to the frequency of the ring oscillator driven by the reference current.

19. The circuit of claim 18, wherein the reference current value is established by a reference circuit based on the simulation of the nominal bit-line parasitics and nominal bit-cell drive current.

20. The circuit of claim 14, wherein the characterized changes from the NTBI stress test is used to determine a level of read assist for proper functioning of the SRAM array over time.
